(19) United States
(12) Patent Application Publication
(10) Pub. No.: US 2025/0211092 A1
(43) Pub. Date: Jun. 26, 2025

(54) POWER RAIL GENERATION SYSTEM

(71) Applicant: Renesas Design (UK) Limited, Bourne End (GB)

(72) Inventors: Pritam CHATTERJEE, Edinburgh (GB); Guillaume DE CREMOUX, Edinburgh (GB)

(73) Assignee: Renesas Design (UK) Limited, Bourne End (GB)

(21) Appl. No.: 18/394,482

(22) Filed: Dec. 22, 2023

(51) Int. Cl. H02M 1/088; H02M 1/00; H02M 3/158

(52) U.S. Cl. CPC H02M 1/088; H02M 1/0067; H02M 3/158

(57) ABSTRACT

A power rail generation system is provided. The system includes a first power rail generator. The first power rail generator is configured to generate a first power rail voltage for a first gate driver. The first gate driver is configured to drive a switching operation of a first power switch of a first switching converter. The first power rail generator is further configured to regulate the first power rail voltage to have a substantially constant first voltage difference from a first local voltage during operation of the first switching converter.

The present disclosure relates to a power rail generation system. In particular the present disclosure relates to a power rail generation system for the generation of a power rail voltage for a gate driver of a switching converter.

### BACKGROUND

FIG. 1 is a schematic of a known output stage of a buck converter 100. The power stage 100 comprises a high side driver 102 for driving a high side PMOS switch 104, and a low side driver 106 for driving a low side NMOS switch 108.

The high side driver 102 comprises a comparator 110 which compares the gate voltage of the PMOS switch 104 with a driver rail GATEP. The low side driver 104 comprises a comparator 112 which compares the gate voltage of the NMOS switch 108 with the driver rail GATEN.

Outputs of comparators 110, 112 are used to turn OFF, for their respective switches 104, 106, direct driving after the gate voltage crosses the 2.5V thresholds. Until gate voltages are below 2.5V thresholds, gates are driven by a current source directly (direct driving) from a voltage VSYS_Bi.

In FIG. 1, a power rail 114 is generated by a low dropout regulator LDO 116 and a power rail 118 is generated by an analog buffer 120.

The features shown in FIG. 1 are as follows:
HS: High Side power device—PMOS
LS: Low Side power device—NMOS
GATEP: Gate of the high side pass device.
GATEN: Gate of the low side pass device.
PCHARGED: Output of the high side driver's comparator which goes high only when GATEP >2.5V threshold i.e., VGS of the HS is close/more than 2.5V and HS is ON
NCHARGED: Output of the low side driver's comparator which goes high only when GATEN>2.5V threshold i.e., VGS of the LS is close/more than 2.5V and LS is ON
BBMAKE: Break Before Make circuit (combinational logic)
MAG: A command signal to magnetize coil, this signal changes from low to high to turn on HS
DEMAG: A command signal to demagnetize coil, this signal changes from low to high to turn on LS
switching frequency of the BUCK, for example 2 MHz: this is the frequency of the power stage.
VSYS_Bi: Switching supply (VIN) same as VDD_SW
VSS_Bi: Switching ground same as VSS_SW
VDD: Clean, Analog supply
VSS: Clean, Analog ground
VDD_DIG: Digital supply
VSS_DIG: Digital ground
gP_cmd: HS Gate command signal, if it is high that means MAG is high, and HS is ON
gN_cmd: LS Gate command signal, if it is low that means DEMAG is high, and LS is ON

Current imbalance between switching converters means that the gate driver circuitry may function inconsistently across different switching converters. Additionally, the requirement for an LDO 116, which is always ON, consumes more than 2 μA DC current and is power inefficient.

### SUMMARY

It is desirable to provide a system for ensuring gate drivers function correctly across multiple switching converters, irrespective of current imbalance between converters.

It is desirable to provide a system for a switching converter, which reduces the power requirements when compared with known systems.

According to a first aspect of the disclosure there is provided a power rail generation system comprising a first power rail generator configured to generate a first power rail voltage for a first gate driver, the first gate driver being configured to drive a switching operation of a first power switch of a first switching converter, and regulate the first power rail voltage to have a substantially constant first voltage difference from a first local voltage during operation of the first switching converter.

Optionally, the first power switch comprises a first transistor.

Optionally, the first gate driver is configured to receive a first switching signal, receive the first local voltage, receive the first power rail voltage, and output a first gate driving signal to the first power switch to drive the switching operation of the first switch.

Optionally, the first gate driver is a first high side driver, the first power switch is a first high side switch and the first local voltage is a first local ground voltage, or the first gate driver is a first low side driver, the first power switch is a first low side switch and the first local voltage is a first local supply voltage.

Optionally, the first switching converter is a buck converter, a boost converter or a buck-boost converter.

Optionally, the first voltage difference is equal to the first local voltage minus the first power rail voltage.

Optionally, the power rail generation system comprises a code generator configured to generate a digital code, and provide the digital code to the first power rail generator, wherein the first power rail generator is configured to generate the first power rail voltage using the digital code.

Optionally, the code generator comprises a bit counter configured to generate the digital code.

Optionally, the bit counter is a 5 bit counter.

Optionally, the bit counter is configured to receive a first clock signal and a digital supply voltage.

Optionally, the power rail generation system comprises a decision circuit configured to provide an up signal and a down signal to the bit counter, wherein the bit counter is configured to generate the digital code based on the up signal and the down signal.

Optionally, the decision circuit comprises a first comparator configured to compare an adaptive voltage with a first reference voltage and to generate a comparator output signal based on the comparison, the up signal and the down signal being dependent on the comparator output signal.

Optionally, the code generator comprises a first adaptive diode configured to receive the digital code and to generate the adaptive voltage based on the digital code.

Optionally, the power rail generation system comprises a first level shifter configured to shift the digital code to a first voltage domain prior to providing the digital code to the first adaptive diode.

Optionally, the first adaptive diode comprises a first resistor divider, a first transistor and a second transistor, wherein the first resistor divider, the first transistor and the second transistor are arranged to generate the adaptive voltage.

Optionally, the power rail generation system comprises a first current source and a first switch, wherein a first clean supply voltage is coupled to the decision circuit and the adaptive diode via the first switch.

Optionally, the first power rail generator comprises a second adaptive diode configured to receive the digital code and to generate the first power rail voltage using the digital code.

Optionally, the first power rail generator comprises a second level shifter configured to shift the digital code to a second voltage domain prior to providing the digital code to the second adaptive diode.

Optionally, the second adaptive diode comprises a second resistor divider, a third transistor and a fourth transistor, wherein the second resistor divider, the third transistor and the fourth transistor are arranged to generate the first power rail voltage.

Optionally, the first local voltage is coupled to the second adaptive diode via a first capacitor.

Optionally, the first power rail generator is configured to generate a second power rail voltage for a second gate driver, the second gate driver being configured to drive a switching operation of a second power switch of the first switching converter, and regulate the second power rail voltage to have a substantially constant second voltage difference from a second local voltage during operation of the first switching converter.

Optionally, the first power switch comprises a first transistor and/or the second power switch comprises a second transistor.

Optionally, the first gate driver is configured to receive a first switching signal, receive the first local voltage, receive the first power rail voltage, and output a first gate driving signal to the first power switch to drive the switching operation of the first switch, and the second gate driver is configured to receive a second switching signal, receive the second local voltage, receive the second power rail voltage, and output a second gate driving signal to the second power switch to drive the switching operation of the second switch.

Optionally, the first gate driver is a first high side driver, the first power switch is a first high side switch and the first local voltage is a first local ground voltage, or the second gate driver is a second low side driver, the second power switch is a second low side switch and the second local voltage is a second local supply voltage.

Optionally, the first switching converter is a buck converter, a boost converter or a buck-boost converter.

Optionally, the first voltage difference is equal to the first local voltage minus the first power rail voltage, and the second voltage difference is equal to the second local voltage minus the second power rail voltage.

Optionally, the power rail generation system of comprises a code generator configured to generate a digital code, and provide the digital code to the first power rail generator, wherein the first power rail generator is configured to generate the first power rail voltage and the second power rail voltage using the digital code.

Optionally, the code generator comprises a bit counter configured to generate the digital code.

Optionally, the bit counter is a 5 bit counter.

Optionally, the bit counter is configured to receive a first clock signal and a digital supply voltage.

Optionally, the power rail generation system comprises a decision circuit configured to provide an up signal and a down signal to the bit counter, wherein the bit counter is configured to generate the digital code based on the up signal and the down signal.

Optionally, the decision circuit comprises a first comparator configured to compare an adaptive voltage with a first reference voltage and to generate a comparator output signal based on the comparison, the up signal and the down signal being dependent on the comparator output signal.

Optionally, the code generator comprises a first adaptive diode configured to receive the digital code and to generate the adaptive voltage based on the digital code.

Optionally, the power rail generation system comprises a first level shifter configured to shift the digital code to a first voltage domain prior to providing the digital code to the first adaptive diode.

Optionally, the first adaptive diode comprises a first resistor divider, a first transistor and a second transistor, wherein the first resistor divider, the first transistor and the second transistor are arranged to generate the adaptive voltage.

Optionally, the power rail generation system comprises a first current source and a first switch, wherein a first clean supply voltage is coupled to the decision circuit and the adaptive diode via the first switch.

Optionally, the first power rail generator comprises a second adaptive diode configured to receive the digital code and to generate the first power rail voltage using the digital code, and a third adaptive diode configured to receive the digital code and to generate the second power rail voltage using the digital code.

Optionally, the first power rail generator comprises a second level shifter configured to shift the digital code to a second voltage domain prior to providing the digital code to the second adaptive diode, and a third level shifter configured to shift the digital code to a third voltage domain prior to providing the digital code to the third adaptive diode.

Optionally, the second adaptive diode comprises a second resistor divider, a third transistor and a fourth transistor, wherein the second resistor divider, the third transistor and the fourth transistor are arranged to generate the first power rail voltage, and the third adaptive diode comprises a third resistor divider, a fifth transistor and a sixth transistor, wherein the third resistor divider, the fifth transistor and the sixth transistor are arranged to generate the second power rail voltage

Optionally, the first local voltage is coupled to the second adaptive diode via a first capacitor, and the second local voltage is coupled to the third adaptive diode via a second capacitor.

Optionally, the power generation system comprises a second power rail generator configured to generate a third power rail voltage for a third gate driver, the third gate driver being configured to drive a switching operation of a third power switch of a second switching converter, and regulate the third power rail voltage to have a substantially constant third voltage difference from a third local voltage during operation of the second switching converter.

According to a second aspect of the disclosure there is provided an apparatus comprising a plurality of switching converters, and a power rail generation system comprising a plurality of power rail generators, wherein each of the switching converters comprises one of the plurality of power rail generators, and each of the power rail generators is configured to generate a power rail voltage for a gate driver of the switching converter that the power rail generator is part of, the gate driver being configured to drive a switching operation of a power switch of the switching converter, and regulate the power rail voltage to have a substantially constant voltage difference from a local voltage during operation of the switching converter.

Optionally, the power rail generation system comprises a code generator configured to generate a digital code, and provide the digital code to each of the power rail generators, wherein each of the power rail generator is configured to generate the power rail voltage using the digital code.

It will be appreciated that the apparatus of the second aspect may include features set out in the first aspect and can incorporate other features as described herein.

According to a third aspect of the disclosure there is provided a method of power rail generation comprising generating a first power rail voltage for a first gate driver, the first gate driver being configured to drive a switching operation of a first power switch of a first switching converter, and regulating the first power rail voltage to have a substantially constant first voltage difference from a first local voltage during operation of the first switching converter.

It will be appreciated that the method of the third aspect may include features set out in the first aspect and/or second aspect and can incorporate other features as described herein.

### BRIEF DESCRIPTION OF THE DRAWINGS

The disclosure is described in further detail below by way of example and with reference to the accompanying drawings, in which:

FIG. 1 is a schematic of a known output stage of a buck converter;

FIG. 2 is a schematic of a buck converter;

FIG. 3A is a schematic of a specific implementation of a first gate driver, FIG. 3B is a schematic of a specific implementation of a second gate driver;

FIG. 4A is a schematic of a power rail generation system in accordance with a first embodiment of the present disclosure;

FIG. 4B is a schematic of a power rail generation system in accordance with a second embodiment of the present disclosure;

FIG. 4C is a schematic of a power rail generation system in accordance with a third embodiment of the present disclosure;

FIG. 5 is an alternative schematic of the buck converter of FIG. 2;

FIG. 6A is a schematic of a power rail generation system in accordance with a fourth embodiment of the present disclosure;

FIG. 6B is a schematic of a power rail generation system in accordance with a fifth embodiment of the present disclosure;

FIG. 7A is a schematic of a power rail generation system;

FIG. 7B is a schematic of a specific implementation of a code generator;

FIG. 7C is a schematic of a specific implementation of an adaptive diode;

FIG. 7D is a schematic of a specific implementation of a decision circuit;

FIG. 7E is a schematic of a specific implementation of the power rail generator;

FIG. 8A is a graph showing simulation results for a practical implementation of the specific implementation of the code generator as shown in FIG. 7B;

FIG. 8B is a further graph showing simulation results for a practical implementation of the specific implementation of the code generator as shown in FIG. 7B;

FIG. 8C is a further graph showing simulation results for a practical implementation of the specific implementation of the code generator as shown in FIG. 7B;

FIG. 8D is a graph showing simulation results for a practical implementation of the specific implementation of the system as shown in FIG. 7A-7E;

FIG. 8E is a graph showing simulation results for a practical implementation of the specific implementation of the system as shown in FIG. 7A-7E;

FIG. 8F is a graph showing simulation results for a practical implementation of the specific implementation of the system as shown in FIG. 7A-7E; and

FIG. 8G is a graph showing simulation results for a practical implementation of the specific implementation of the system as shown in FIG. 7A-7E.

### DETAILED DESCRIPTION

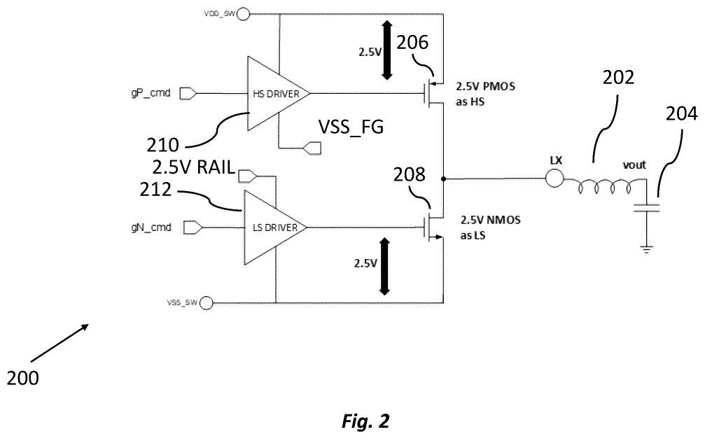

FIG. 2 is a schematic of a buck converter 200 comprising an inductor 202, a capacitor 204, switches 206, 208, and gate drivers 210, 212. It will be appreciated that the present schematic represents a general implementation of the output stage 100, where the switches 206 and 208 correspond to the switches 104 and 108, respectively, and the gate drivers 210 and 212 correspond to the gate drivers 102 and 106, respectively.

The gate driver 210 is a high side driver circuit. During operation, the gate driver 210 receives a command signal gP_cmd as input and drives the switch 206 to magnetize the inductor 202.

A power rail voltage VSS_FG is used as the ground for the gate driver 210. In the present example, the power rail voltage VSS_FG is 2.5V below a local voltage VDD_SW, so that when the command signal gP_cmd goes high, the switch 206 can get 2.5V (gate-to-source voltage) VGS to become fully ON.

The gate driver 212 is a low side driver circuit. The gate driver 212 receives a command signal gN_cmd as input and drives the switch 208 to demagnetize the inductor 202.

In the present example, a power rail voltage 2.5V RAIL is the required rail which is used as the supply rail for gate driver 212. The power rail voltage 2.5V RAIL is 2.5V higher than a local voltage VSS_SW so that when the command signal gN_cmd goes high, the switch 208 can get 2.5V VGS to become fully ON.

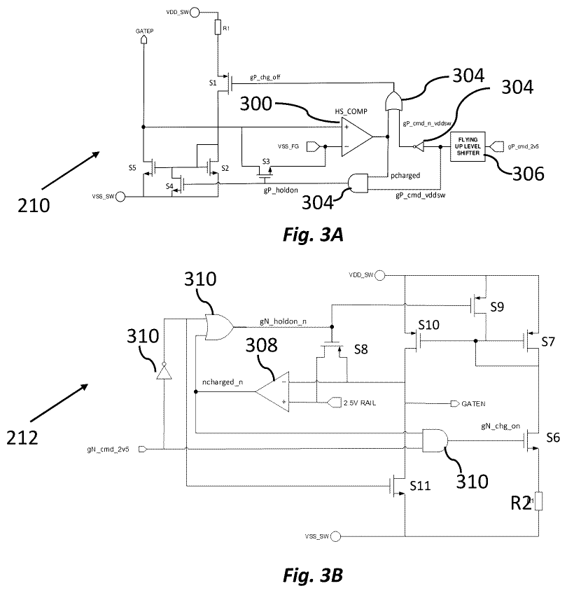

FIG. 3A is a schematic of a specific implementation of the gate driver 210. The gate driver 210 comprises a comparator 300, switches S1, S2, S3, S4, S5, a resistor R1, logic gates 304 and a level shifter 306.

During operation the comparator compares a gate voltage GATEP and the power rail voltage VSS_FG (floating rail which is 2.5V below from VDD_SW). At the start of the magnetization cycle, GATEP is discharged from VDD_SW through switch S5 and comes closer to VSS_FG. Output of the comparator 300 goes high when GATEP crosses a threshold value, the threshold value being equal to VSS_FG minus a systematic comparator offset threshold, and that turns ON switch S3 which shorts VSS_FG with GATEP to turn ON the switch 206. During the demagnetization cycle, the command signal gP_cmd is low and that turns ON switch S4 to pull down the gate of switch S2 and the switch S5. The discharge path of GATEP (being switch S5) is cut off and GATEP is pulled up to VDD_SW to ensure turn OFF of the switch 206.

FIG. 3B is a schematic of a specific implementation of the gate driver 212. The gate driver 212 comprises a comparator 308, switches S6, S7, S8, S9, S10, S11, a resistor R2, and logic gates 310.

During operation, the comparator 308 compares a gate voltage GATEN and the power rail voltage 2.5V RAIL. At the start of the demagnetization cycle, the gate voltage GATEN is charged through the switch S9 and comes closer to the power rail voltage 2.5V RAIL. The output of the comparator 308 ncharged_n goes low when the gate voltage GATEN crosses a threshold value, the threshold value being equal to 2.5V RAIL minus a systematic COMP offset and that turns ON the switch S8 (PMOS) which shorts the power rail voltage 2.5V RAIL with the gate voltage GATEN to turn ON the switch 208. During the demagnetization the command signal gN_cmd is low and that turns ON the switch S11 to pull down the gate voltage GATEN to the local voltage VSS_SW, simultaneously charging current source is also pulled up to local voltage VDD_SW.

In the present example, there is required the generation of 2.5V VGS for the switches 206, 208 and it is preferable that the whole design should not consume more than 2 μA DC current when the switches 206, 208 are not switching.

Also, the voltages of the power rails (VSS_FG and 2.5V RAIL) should be well defined with respect to the local voltage (VDD_SW and VSS_SW) respectively for the, so that the digital logic and comparators can reliably operate to send correct ON/OFF signals and ensure appropriate switching sequence for both the power devices 206, 208.

As discussed previously, VDD is the clean analog supply voltage. VDD_SW denotes the local supply voltage to the switching converter 200 and subject to variation due to current imbalances (for example, due to variations in load current).

Therefore, for a system comprises multiple switching converters, each converter may receive the same clean supply voltage VDD. The supply voltage used by the switching converter will be subject to variation due to the operation of the switching converter—this distinction is made by referring to a local supply voltage VDD_SW for a given switching converter. The multiple switching converters may have different local supply voltages VDD_SW due to current imbalances between switching converters.

Similarly, VSS denotes the clean analog supply voltage, being a ground voltage, with VSS_SW being the local supply voltage to a specific switching converter and subject to variation due to current imbalances (for example, due to variations in load current).

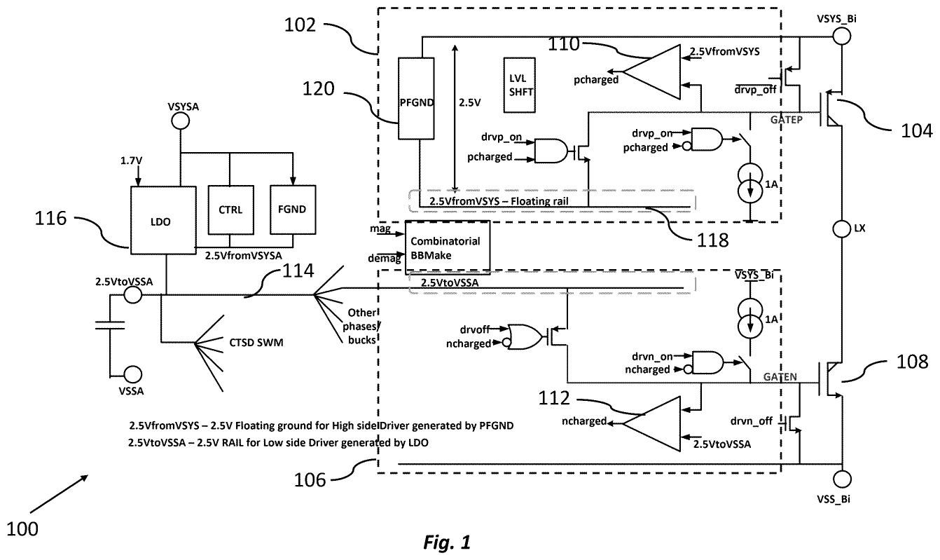

The direct driving scheme as illustrated in FIG. 2, FIG. 3A and FIG. 3B uses two power rails, one power real being for each of the drivers 210, 212. If these two power rails are generated from a LDO (2.5V RAIL, for example as shown in FIG. 1—the buffer 120) and analog buffer (VSS_FG, for example as shown in FIG. 1—the LDO 116), it does not serve the requirements, this direct driving scheme has the following disadvantages:
Power rail generation requires at least one LDO which is always ON and consumes much more than 2 uA DC current and power inefficient.
A problem with generating 2.5V through any LDO is determining what should be the ground for the LDO. Due to a high load current flowing through the power distribution network, the local voltage VSS_SW will have a peak to peak variation in voltage exceeding 2V i.e. a >2V bounce. If the LDO output is referenced to the clean ground voltage VSS, then due to the local voltage VSS_SW bounce, sometimes VGS for the switch 208 would be only either 1.5V (+1V bounce on VSS_SW) or 3.5V (−1V bounce on VSS_SW). A similar issue arises for the switch 206 due to bounce on the local voltage VDD_SW.
1.5V VGS on a power device (for example, one of switch 206, 208) results in an increased on resistance R_ON which is detrimental for a switching converter's efficiency
3.5V VGS on power device (for example, on of switch 206, 208) may damages the device as it is a SOA (Safe Operating Area) violation.
One input of the comparator (2.5V Rail, coming from 2.5V LDO or VSS_FG, coming from buffer) is referenced to clean ground and other input is coming from power device's gate which are referenced to switching ground (VSS_SW) or switching supply (VDD_SW). Therefore, comparators which are sensing the switch 206, 208 gate nodes always toggle.

Embodiments of the present disclosure aim to resolve one or more of the aforementioned disadvantages, by providing a new system for power rail generation.

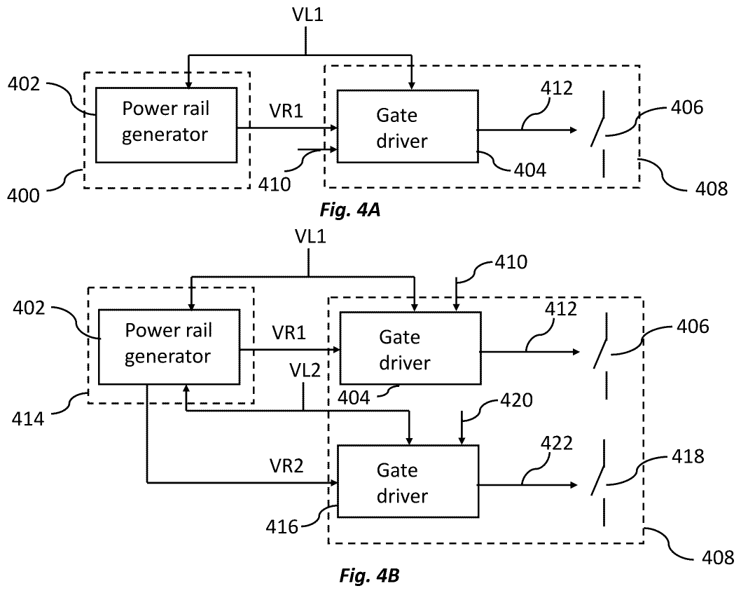

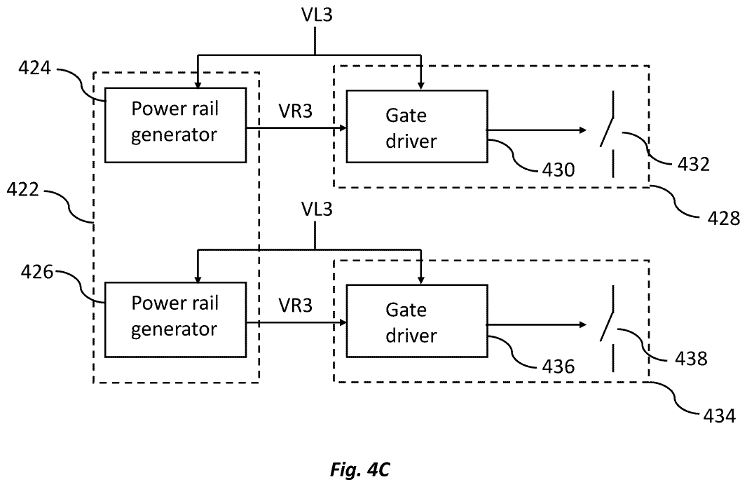

FIG. 4A is a schematic of a power rail generation system 400 in accordance with a first embodiment of the present disclosure. The power rail generation system 400 comprises a power rail generator 402 that is configured to generate a power rail voltage VR1 for a gate driver 404.

During operation, the gate driver 404 drives a switching operation of a power switch 406 of a switching converter 408. The switch 406 may comprise a transistor. The switching converter 408 may, for example, be a buck converter, a boost converter or a buck-boost converter.

The power rail generator 402 is further configured to regulate the power rail voltage VR1 to have a substantially constant voltage difference AV1 from a local voltage VL1 during operation of the switching converter 408. The voltage difference may, for example, be provided by the following equation:

ΔV1=VL1−VR1 (1)

The gate driver 404 may be configured to receive a switching signal 410, receive the local voltage VL1 and output a gate driving signal 412 to the power switch 406 to drive the switching operation of the switch 406. A power switch may be referred to as a “power device”.

It will be appreciated that the power rail generation system 400 may be, for example, used to generate the required power rail voltages for the system as described in FIG. 2, FIG. 3A and FIG. 3B.

For example, the power rail voltage VR1 may correspond to VSS_FG, with the local voltage VL1 corresponding to VDD_SW, the gate driver 404 corresponding to the gate driver 210, and the switch 406 corresponding to the switch 206. In a further embodiment, the power rail voltage VR1 may correspond to 2.5V RAIL, with the local voltage VL1 corresponding to VSS_SW, the gate driver 404 corresponding to the gate driver 212, and the switch 406 corresponding to the switch 208. Furthermore, two implementations of the system 400 may be used to generated both power rail voltages.

FIG. 4B is a schematic of a power rail generation system 414 in accordance with a second embodiment of the present disclosure. Compared to the power rail generation system 400, the power rail generator 402 is further configured to generate a power rail voltage VR2 for a gate driver 416. The gate driver 416 is configured to drive the switching operation of a switch 418 of the switching converter 408. The switch 418 may comprise a transistor.

The power rail generator 402 is further configured to regulate the power rail voltage VR2 to have a substantially constant voltage difference AV2 from a local voltage VL2 during operation of the switching converter 408. The voltage difference may, for example, be provided by the following equation:

ΔV2=VL2−VR2 (2)

The gate driver 416 may function as described for the gate driver 404, with the gate driver receiving a switching signal 420, the local voltage VL2, the power rail voltage VR2 and outputting a gate driving signal 422 for controlling the switching of the switch 418.

It will be appreciated that the power rail generation system 404 may be, for example, used to generate both of the required power rail voltages for the system as described in FIG. 2, FIG. 3A and FIG. 3B. For example, VR1 may correspond to VSS_FG and VR2 may correspond to 2.5V RAIL.

FIG. 4C is a schematic of a power rail generation system 422 in accordance with a third embodiment of the present disclosure. In the present example there are two power rail generators 424, 426 which each may function as any of the power rail generators as described herein, in accordance with the understanding of the skilled person.

The power rail generator 424 is configured to generate a rail voltage VR3 for a switching converter 428 comprising a gate driver 430 and a switch 432. The rail voltage VR3 is regulated by the power rail generator 424 to have a substantially constant voltage difference from a local voltage VL3 during operation.

The power rail generator 426 is configured to generate a rail voltage VR4 for a switching converter 434 comprising a gate driver 436 and a switch 438. The rail voltage VR4 is regulated by the power rail generator 426 to have a substantially constant voltage difference from a local voltage VL4 during operation.

Although illustrated for two switching converters, it will be appreciated that in further embodiments there may be provided more than two power rail generators to generate the power rail voltages for more than two switching converters. Furthermore, in further embodiments having a plurality of power rail generators, each of the power rail generators associated with a single switching converter may be configured to generate more than one power rail voltage, for example as illustrated in FIG. 4B, and may be used to generate power rail voltages for high and low side gate drivers, in accordance with the understanding of the skilled person.

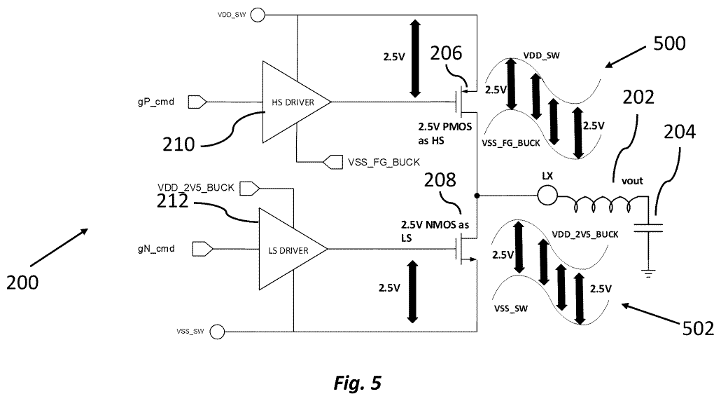

FIG. 5 is an alternative schematic of the buck converter 200 of FIG. 2, showing the buck converter 200 having received the rail voltages as may be provided by a power rail generation system of the present disclosure, for example, the power rail generation system 414 as shown in FIG. 4B. In the present example, the power rail voltage VSS_FG_BUCK corresponds to the power rail voltage VSS_FG as previously discussed and may be provided by the power rail voltage VR1. In the present example, the power rail voltage VDD_2V5_BUCK corresponds to the power rail voltage 2.5V RAIL as previously discussed and may be provided by the power rail voltage VR2.

A graph 500 shows a comparison between the local voltage VDD_SW and the power rail voltage VSS_FG_BUCK. A graph 502 shows a comparison between the local voltage VSS_SW and the power rail voltage VDD_2V5_BUCK. As can be observed, using the power generation system 414 ensures that the voltage differences ΔV1, ΔV2 as provided by equations (1) and (2), respectively, remains constant during operation, and irrespective of variation in the local voltages VDD_SW, VSS_SW.

V

DD_2V5_BUCK and VSS_FG_BUCK are the two local rails to each phase which are coupled to VSS_SW and VDD_SW respectively. VDD_2V5_BUCK and VSS_FG_BUCK maintain the 2.5V difference (VGS for power devices) from VSS_SW and VDD_SW respectively.

In summary the power rail generator systems of the present disclosure ensure that the power rails used for the gate drivers are well referenced (coupled) to VDD_SW for the high side gate driver and VSS_SW for the low side gate driver so that the comparators can make correct decisions on the gate voltages of the associated power switches.

As discussed previously, a mismatch in current flowing in two different phases can create imbalance in ground or supply bounces. If one central LDO or buffer provides rails to all the drivers (phases), each driver would be imbalanced and can get an incorrect decision on switching (for example as may occur when using the system of FIG. 1).

The use of an LDO also means that power rails can get drastically disturbed (overshoot/undershoot) due to fast charging/discharging of power device gate nodes. For example, if these two rails are coming from any LDO or similar design it would suffer huge overshoot/undershoot (>1V) to support transient currents to charge/discharge gates quickly (<10 ns). Embodiments of the present disclosure prevent this occurrence.

If we want to design rail for each phase using LDO/buffer (for example as shown in FIG. 1), then we need to design LDO with very minimal quiescent current so that we do not exceed target 2 μA current consumption specification. However, an LDO with <250 nA (considering 8 output stages to drive) current consumption specification is would not be able to meet the super-fast load transient specifications which will ensue failure in driver operation. Embodiments of the present disclosure do not result in failure in driver operation, for a current consumption less than 2 μA.

In summary, embodiments of the present disclosure avoid the coupling issue for VSS_FG_BUCK to the VDD_SW, as there is no dependency on any central supply for power rail generation. Specifically, embodiments of the present disclosure can locally generate a floating rail VSS_FG_BUCK inside each phase. Now this floating rail, VSS_FG_BUCK is locally coupled to VDD_SW. Similarly, for the low side there is no dependency anymore on any central block or LDO output as required by known systems. Rather, embodiments of the present disclosure, can locally generate 2.5V rail VDD_2V5_BUCK inside each phase.

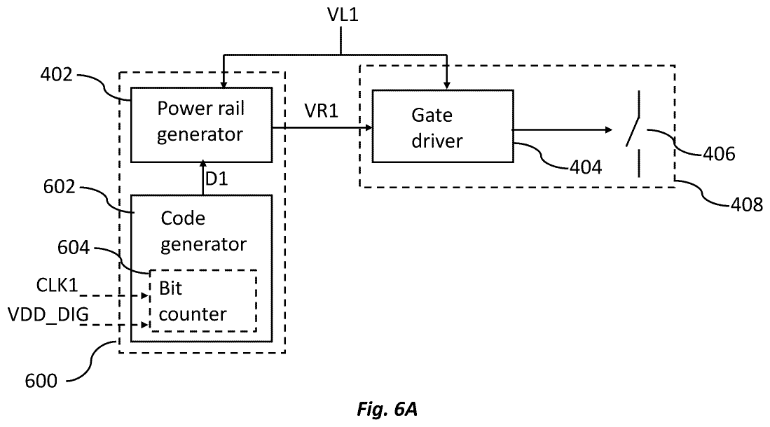

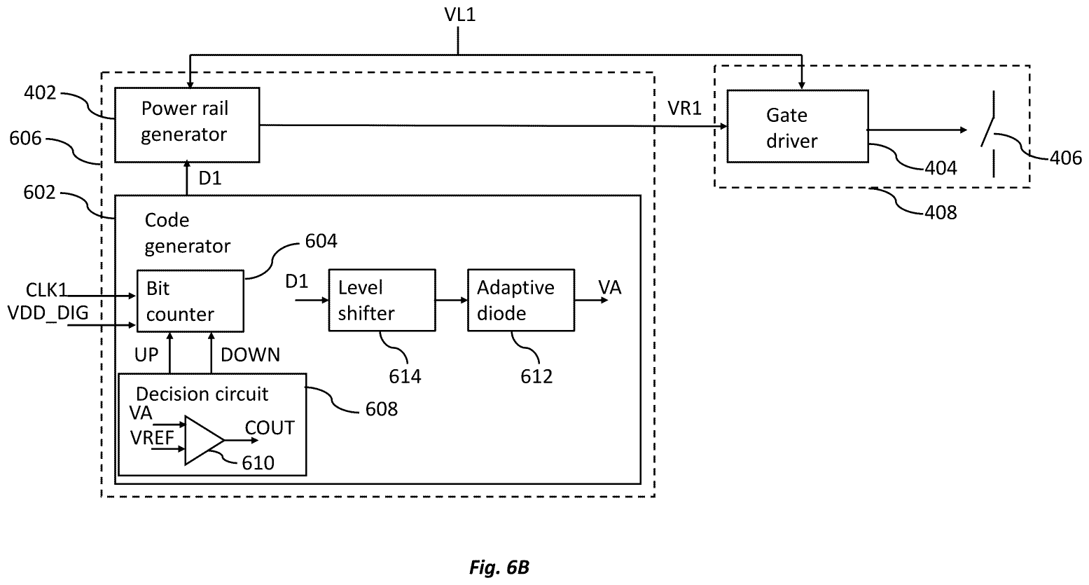

FIG. 6A is a schematic of a power rail generation system 600 in accordance with a fourth embodiment of the present disclosure. In the present embodiment, the power rail generation system 600 further comprises a code generator 602 configured to generate a digital code D1 and to provide the digital code D1 to the power rail generator 402. The power rail generator 402 is configured to generate the power rail voltage VR1 using the digital code D1. The code generator 602 may comprise a bit counter 604 configured to generate the digital code D1. The bit counter 604 may, for example, be a 5 bit counter. The bit counter 604 may be configured to receive a clock signal CLK1 and a digital supply voltage VDD_DIG.

FIG. 6B is a schematic of a power rail generation system 606 in accordance with a fifth embodiment of the present disclosure. The power rail generation system 606 comprises a decision circuit 608 that is configured to provide an up signal UP and a down signal DOWN to the bit counter 604. The bit counter 604 is configured to generate the digital code D1 based on the signals UP, DOWN.

The decision circuit 608 may comprise a comparator 610 that compares an adaptive voltage VA with a reference voltage VREF and generates an output signal COUT. The signals UP, DOWN are dependent on the output signal COUT.

The code generator 602 may comprise an adaptive diode 612 configured to receive the digital code D1 and to generate the adaptive voltage VA based on the digital code D1.

The power rail generation system comprises a level shifter 614 that is configured to shift the digital code D1 to a first voltage domain prior to providing the digital code D1 to the adaptive diode 612.

The primary advantage of sending the digital code D1 and level shifting it to vdd_2v5_buck domain, for example as may be provided by the level shifter 614, is that the code D1 is immune to supply bounces.

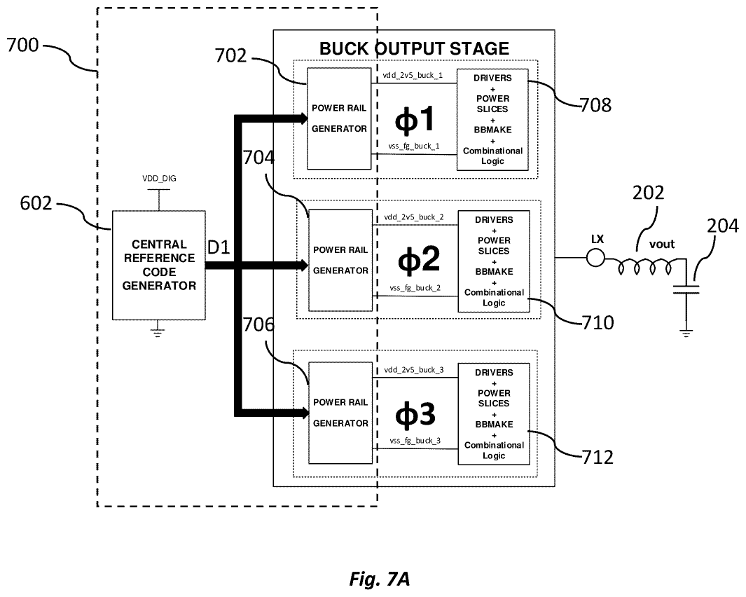

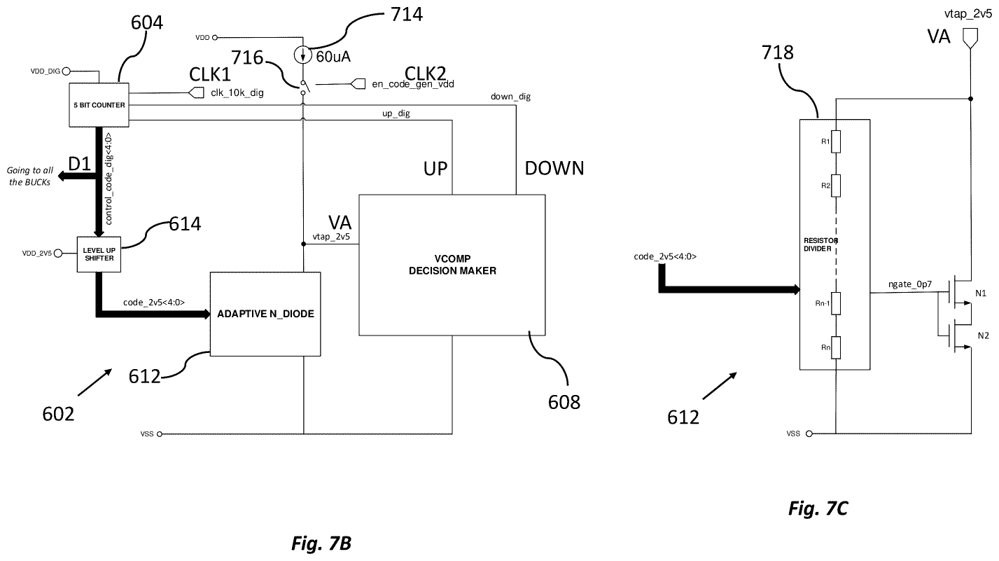

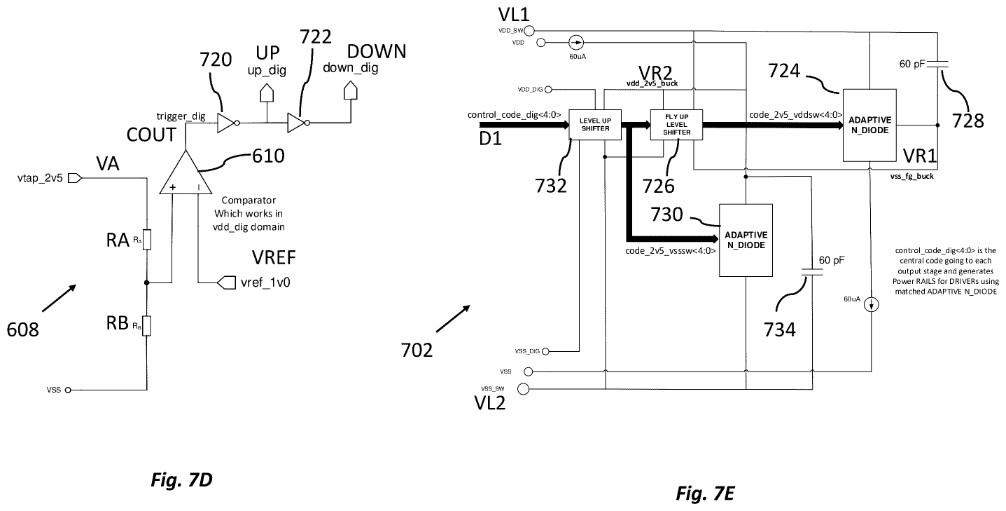

FIG. 7A is a schematic of a power rail generation system 700 comprising power rail generators 702, 704, 706 each coupled to drivers 708, 710, 712. The power rail generators 702, 704, 706 may be implemented using any of the embodiments described herein, in accordance with the understanding of the skilled person.

In the present example, driver rails (for example vdd_2v5_buck_1 and vss_fg_buck_1) are generated within each phase and coupled to the phase specific local VDD_SW and VSS_SW. As discussed previously, generating power rails locally has a great advantage of not getting corrupted or disturbed by the bounces on VDD_SW/VSS_SW of other BUCKs/phases of the whole chip.

In the present example, there is provided one central reference code generator 602 which can stay in the clean supply voltage VDD domain and the clean ground voltage VSS domain inside an analog core of a chip.

This code generator 602 generates the digital code D1, which is sent to all of the buck converters (different phases) throughout the chip. In the present example, three buck converters are shown.

The buck output stage receives the code D1 and uses it to generate local power rails inside each phase using the local power rail generator. In the present example, there are 3 phases, and each phase generates their own local rails vdd_2v5_buck_1/2/3 and vss_fg_buck_1/2/3 respectively.

The power rail generation system 700 can maintain the quality of rails (vdd_2v5_buck and vss_fg_buck) by quickly delivering transient current to output stage drivers.

Additionally, there is zero always ON current required inside the power rail generator system 700. The power rail generator system 700 requires power only when the buck converter output stage starts switching.

Also, the central reference code generator 602 may be enabled using a 10 KHz clock and it does not need any DC current to produce the digital code D1. This is a great advantage over any conventional LDO/analog buffer-based rail design method.

FIG. 7B is a schematic of a specific implementation of the code generator 602. In the present example, the adaptive diode 612 is labelled ADAPTIVE N_DIODE and the decision circuit 608 is labelled VCOMP DECISION MAKER. Input to the adaptive diode 612 is digital code D1 in the 2.5V domain, as provided by the level shifter 614. A current source 714 is coupled to the adaptive diode 612 via a switch 716. The 60 μA current source 714 is sourced to the diode 612 and operation of the current source 714 is synchronised with a 10 kHz clock CLK2.

The decision circuit 608 receives the adaptive voltage VA (also labelled vtap_2v5) as an input and generates two triggers UP (also labelled up_dig) and DOWN (also labelled down_dig).

The decision circuit 608 operates in the VDD_DIG domain and its outputs are sent to the 5 BIT counter 604. Depending on the UP or DOWN triggering, the counter 604 generates the central code D1. This central code D1 in digital domain is the output of the central code reference generator 602. The clock signal CLK1 (also labelled clk_10k_dig) is the clock provided to the 5-bit counter 604.

FIG. 7C is a schematic of a specific implementation of the adaptive diode 612. The adaptive diode 612 comprises a resistor divider 718, and transistors N1, N2. The resistor divider 718 and the transistors N1, N2 are arranged to generate the adaptive voltage VA.

The resistor divider 718 is a programmed resistor divider and the adaptive diode 612 is an NMOS device. This resistive ladder 718 is programmed by the level shifted code (the counter 604 output) and generates adaptive voltage VA (also labelled vtap_2v5 (2.5V)) and that vtap_2v5 is referenced to VSS.

In FIG. 7B, the adaptive voltage VA (also labelled vtap_2v5) is generated by the adaptive diode 612. In the present embodiment, the adaptive diode 612 comprises a 2.5V NMOS diode (N1, N2) and the resistor ladder 718.

Digital codes are used to turn ON/OFF switches (2.5V domain device) which are inside the programmable resistor ladder 718. Without correct switching ON/OFF of the switches inside the resistor ladder 718, the adaptive voltage VA voltage can be corrupted.

In the present example, digital code comes from a digital domain and those digital bits are level shifted UP to turn ON/OFF switches inside the resistor ladder 718, and are shifted to a 2.5V domain signal to ensure correct and reliable turning ON/OFF of the 2.5V domain switches. The level shifter 614 provides this functionality.

The level shifters 614 level shift between the digital domain (for example VDD_DIG, VSS_DIG) to another suitable domain (for example VDD, VSS domain).

FIG. 7D is a schematic of a specific implementation of the decision circuit 608. The decision circuit comprises resistors RA, RB and digital gates 720, 722.

The comparator 610 operates in the VDD_DIG domain and compares the divided version (programmed resistor divider's output) of the adaptive voltage VA (vtap_2v5 node) with the reference voltage VREF, where the reference voltage VREF is equal to 1V in the present example and is provided by a bandgap reference. The comparator output COUT (also labelled trigger_dig) goes high when divided version of vtap_2v5 is more than the reference voltage VREF.

FIG. 7E is a schematic of a specific implementation of the power rail generator 702. It will be appreciated that the implementation illustrated in FIG. 7E may be used for implementation of the power generator 704, the power generator 706 or any other power generator described herein in accordance with the understanding of the skilled person. This block is local to each phase inside the BUCK converter.

The power rail generator 702 comprises an adaptive diode 724 configured to receive the digital code D1 and to generate the power rail voltage VR1. The power rail generator 702 comprises a level shifter 726 configured to shift the digital code D1 to a second voltage domain prior to providing the digital code D1 to the adaptive diode 724.

The adaptive diode 724 may be implemented using a resistive divider and transistors arranged as shown in FIG. 7C. In the present example for the adaptive diode 724, the resistive divider 718 would receive the digital code D1 in the appropriate voltage domain, the output would be the power rail voltage VR1 instead of the adaptive voltage VA, and the supply voltage would be a local supply voltage rather than the clean supply voltage VSS as shown in FIG. 7C. The local voltage VL1 is coupled to the adaptive diode 724 via a capacitor 728.

The power rail generator 702 comprises an adaptive diode 730 configured to receive the digital code D1 and to generate the power rail voltage VR2. The power rail generator 702 comprises a level shifter 732 configured to shift the digital code D1 to a third voltage domain prior to providing the digital code D1 to the adaptive diode 730.

The adaptive diode 730 may be implemented using a resistive divider and transistors arranged as shown in FIG. 7C. In the present example for the adaptive diode 730, the resistive divider 718 would receive the digital code D1 in the appropriate voltage domain, the output would be the power rail voltage VR2 instead of the adaptive voltage VA, and the supply voltage would be a local supply voltage rather than the clean supply voltage VSS as shown in FIG. 7C. The local voltage VL2 is coupled to the adaptive diode 730 via a capacitor 734.

The power rail generator 702 generates VR2 (vdd_2v5_buck, 2.5V RAIL for the output stage) and VR1 (vss_fg_buck, Floating Rail/VSS_FG). These are two power rail voltages which are local to each phase as described previously.

It will be appreciated that in a further embodiment, the power rail generator may only comprise a single adaptive diode to provide a single power rail voltage, in accordance with the understanding of the skilled person.

This block comprises two matched ADAPTIVE N_DIODE 724, 730 which may be implemented using the same circuit as provided within the Central Reference Code Generator 602 as shown in FIG. 7C.

Also, 60 pF capacitors 728, 734 are connected between the generated rails and corresponding referenced rails to help with sudden transient current requirements.

Input to this block is coming from central reference code generator 602 in the VDD_DIG domain, hence the level shifter 732 is used to level shift up the digital code D1 from the VDD_DIG domain to the vdd_2v5_buck domain.

Level shifted codes are sent to the adaptive diode 730 which regulates 2.5V delta from VSS_SW, hence vdd_2v5_buck is always 2.5V higher than local VSS_SW and becomes immune to any disturbances/imbalances from other BUCK converters of the chip.

The above description relates to the low side operation, and a similar operation is provided for the high side, where an output of the level shifter 732 is provided to the level shifter 726 which level shifts up the incoming code from vdd_2v5_buck, VSS_SW domain to VDD_SW, vss_fg_buck domain.

Level shifted codes code_2v5_vddsw<4:0> are sent to adaptive N_DIODE 724 which is coupled between VDD_SW and vss_fg_buck. This N_DIODE 724 maintains 2.5V delta from VDD_SW, hence vss_fg_buck is always lower than local VDD_SW and becomes immune to any disturbances/imbalances from other BUCK converters of the chip.

The adaptive N_DIODE 730 to generate vdd_2v5_buck is given a 60 μA current source which is ON only when the buck converter is switchingi.e., when vdd_2v5_buck rail would be required to drive low side switching. The adaptive diode N_DIODE 724 which is used to generate vss_fg_buck is given a 60 μA sink current which is ON only when the buck converter is switching i.e., when vss_fg_buck rail would be required to drive high side switching.

Even with <10 ns rise/fall time of gate GATEP and GATEN, local power rails are good enough to drive output stage reliably and ensure correct ON/OFF sequences.

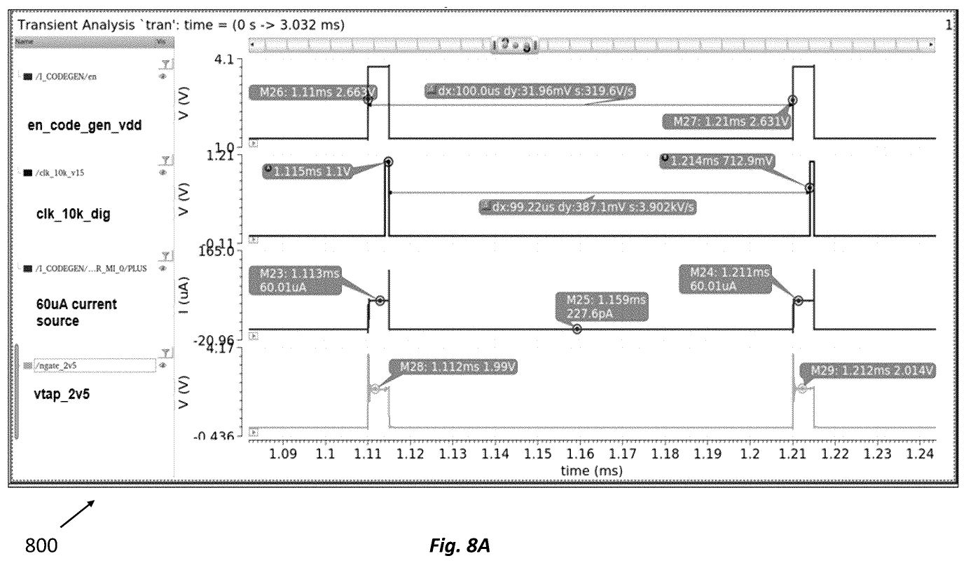

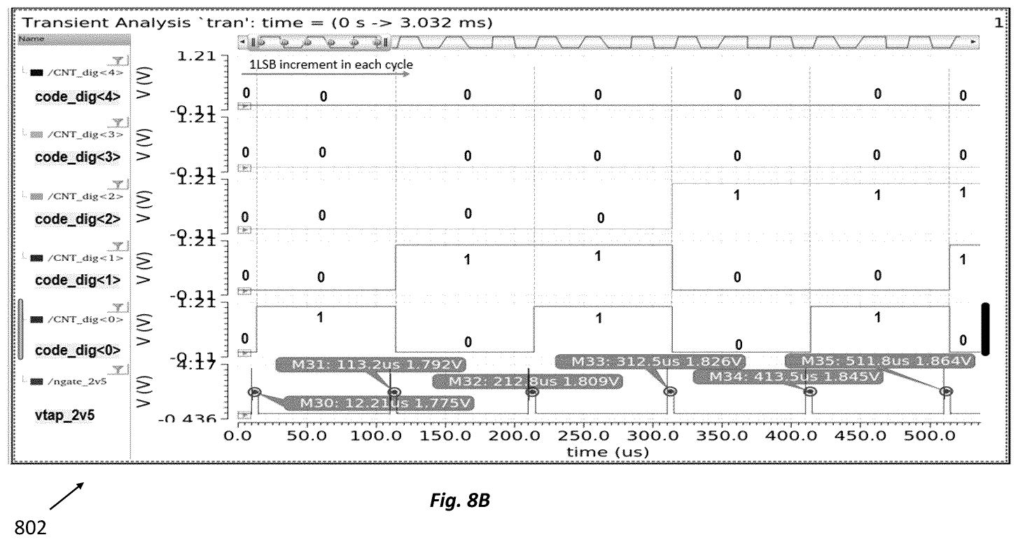

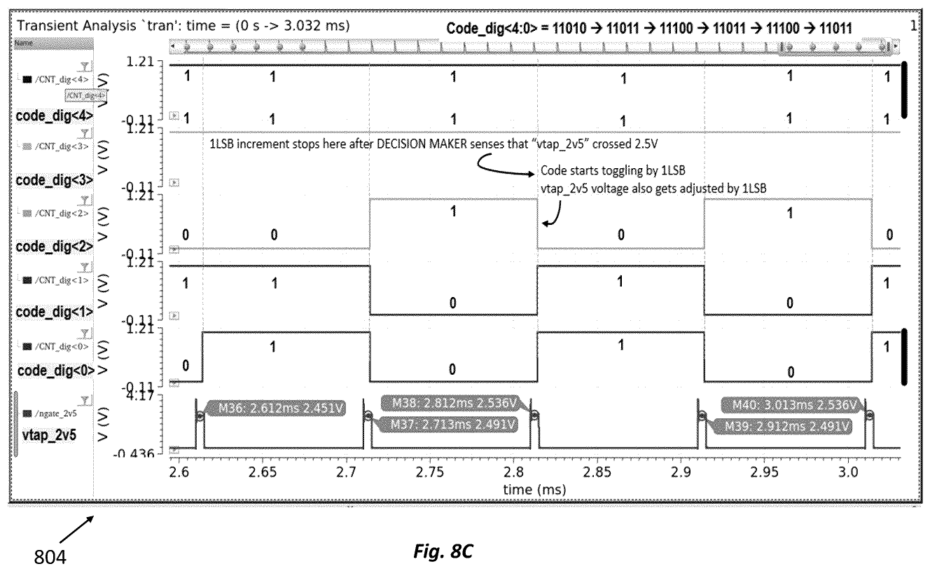

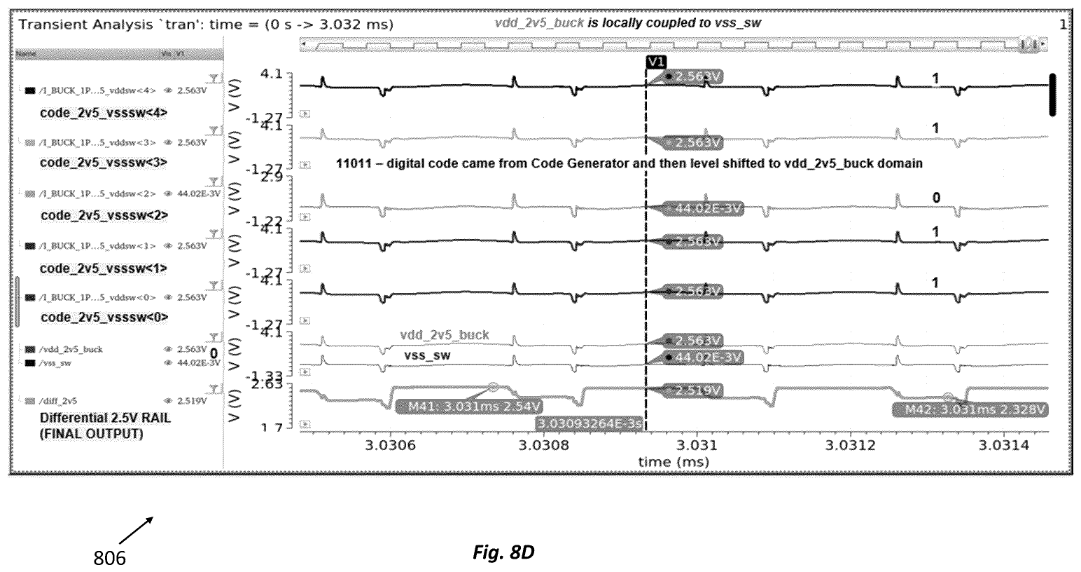

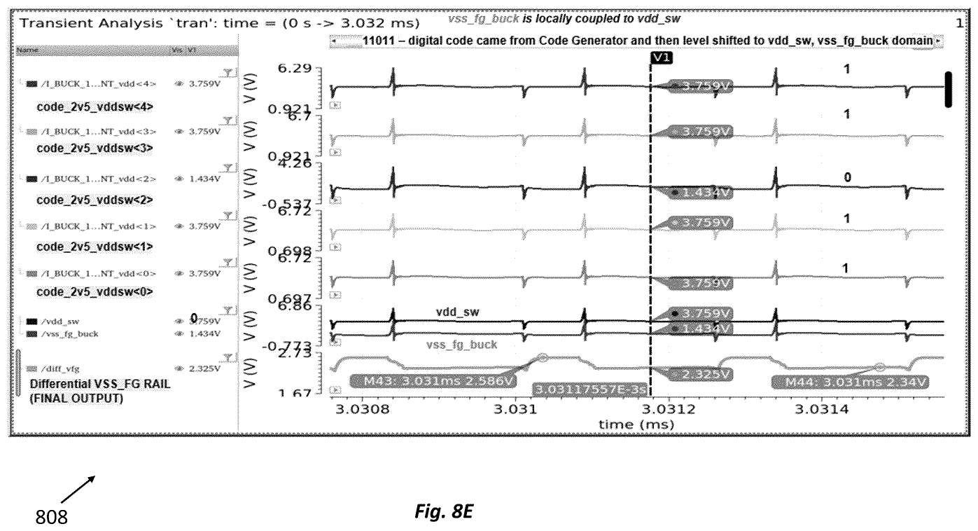

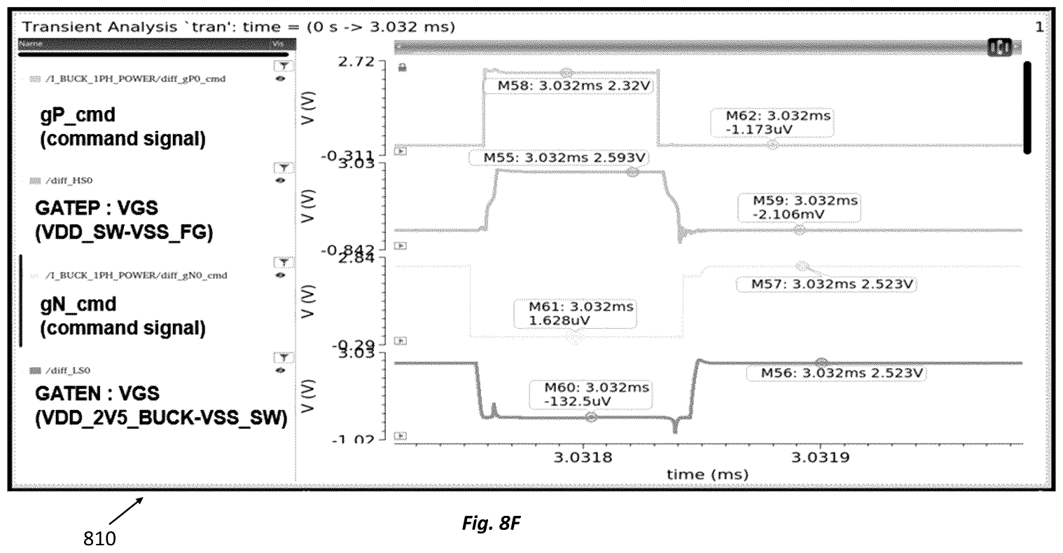

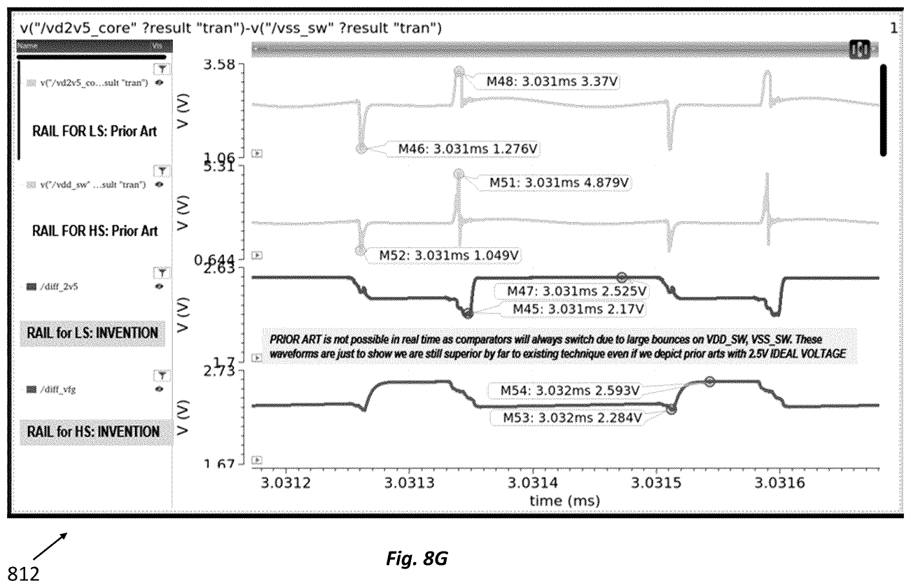

FIG. 8A is a graph 800 showing simulation results for a practical implementation of the specific implementation of the code generator 602 as shown in FIG. 7B.

A trace, en_code_gen_vdd (Enable of the code generator, which is synced with clock of 10 KHz and has pulse width of 10 μs) and a trace, clk_10k_dig (clock to the 5-bit counter with 5 μs pulse width) are shown. Also, a trace, 60 μA source current to the ADAPTIVE N_DIODE and a trace, vtap_2v5 node are shown. It can be observed there is no current to the N_DIODE when en_code_gen_vdd goes low.

FIG. 8B is a further graph 802 showing simulation results for a practical implementation of the specific implementation of the code generator 602 as shown in FIG. 7B.

It can be observed that vtap_2v5 node is increasing in each cycle. This vtap_2v5 node voltage increases in each cycle through 1 LSB increment in 5-bit counter output (code). At the very beginning 5-bit counter is reset, hence digital code starts with 00000.

FIG. 8C is a further graph 804 showing simulation results for a practical implementation of the specific implementation of the code generator 602 as shown in FIG. 7B.

FIG. 8C shows that when vtap_2v5 is more than 2.5V that same counter toggles 1 LSB down to bring vtap_2v5 node voltage close to 2.5V through ADAPTIVE_NDIODE. Hence at steady state operation, vtap_2v5 will toggle near 2.5V through 1 LSB toggling of counter output as 5-bit outputs will be also toggling in steady state by 1 LSB.

FIG. 8D is a graph 806 showing simulation results for a practical implementation of the specific implementation of the system as shown in FIG. 7A-7E.

FIG. 8D shows simulation results from the BUCK's output stage where all the control bits are level shifted up to vdd_2v5_buck level (local to each phase). Also, 2.5V RAIL for LS i.e., “vdd_2v5_buck” is shown with switching ground VSS_SW. Finally at the bottom, we have shown the differential signal going to LS gate which is locally referenced to VSS_SW i.e., (vdd_2v5_buck-VSS_SW).

FIG. 8E is a graph 808 showing simulation results for a practical implementation of the specific implementation of the system as shown in FIG. 7A-7E.

FIG. 8E shows simulation results from the BUCK's output stage where all the control bits are level shifted up between VDD_SW, vss_fg_buck domains (local to each phase). Also, 2.5V RAIL for HS i.e., “vss_fg_buck” is shown with switching supply VDD_SW. Finally at the bottom, we have shown the differential signal going to HS gate which is locally referenced to VDD_SW i.e., (VDD_SW-vss_fg_buck).

FIG. 8F is a graph 810 showing simulation results for a practical implementation of the specific implementation of the system as shown in FIG. 7A-7E.

FIG. 8F shows that for HS and LS-both gates are reliably switching and maintaining correct ON/OFF sequences without getting drastically low or high.

FIG. 8G is a graph 812 showing simulation results for a practical implementation of the specific implementation of the system as shown in FIG. 7A-7E.

FIG. 8G shows that even if a system mimics 2.5V Rail (LS) and floating grounds (HS) with ideal voltage sources, and also does not consider switching of driver comparators (due to large load current ensuing bounces on VDD_SW, VSS_SW)—embodiments of the present disclosure provide superior performance.

In summary, embodiments of the present disclosure do not use/depend on any central supply, for example any central LDO. Embodiments of the present disclosure locally generate local power rails inside each phase for every BUCK in the whole chip.

Embodiments of the present disclosure do not require an area in-efficient (OFF-Chip) capacitor like known systems (any conventional LDO) which must support superfast (<6 ns) charging as well as discharging of the big amount of gate capacitances of HS and LS power devices.

Embodiments of the present disclosure solves the problem of ground/supply imbalances as the rail generation is local to each phase. An advantage of embodiments of this disclosure is that it can work seamlessly with the help of central digital code. Use of digital code and level shifting are beneficial because digital codes are immune to supply/ground bounces.

Embodiments of the disclosure do not need any always ON block which would have consumed DC current. For example, the Central Reference Code Generator is ON with a 10 KHz clock of 10 μs on time. Also, inside output stage, POWER RAIL GENERATOR is using current source (LS RAIL) and current sink (HS RAIL) only when we start switching (at the de-assertion of tristate) the output stages.

Various improvements and modifications can be made to the above without departing from the scope of the disclosure.

1. A power rail generation system comprising:
a first power rail generator configured to:
generate a first power rail voltage for a first gate driver, the first gate driver being configured to drive a switching operation of a first power switch of a first switching converter; and
regulate the first power rail voltage to have a substantially constant first voltage difference from a first local voltage during operation of the first switching converter.

2. The power rail generation system of claim 1, further comprising:
a code generator configured to:
generate a digital code; and
provide the digital code to the first power rail generator;
wherein the first power rail generator is configured to generate the first power rail voltage using the digital code.

3. The power rail generation system of claim 2, wherein the code generator comprises a bit counter configured to generate the digital code.

4. The power rail generation system of claim 3, wherein the bit counter is configured to receive a first clock signal and a digital supply voltage.

5. The power rail generation system of claim 4, further comprising a decision circuit configured to provide an up signal and a down signal to the bit counter, wherein the bit counter is configured to generate the digital code based on the up signal and the down signal.

6. The power rail generation system of claim 5, wherein the decision circuit comprises a first comparator configured to compare an adaptive voltage with a first reference voltage and to generate a comparator output signal based on the comparison, the up signal and the down signal being dependent on the comparator output signal.

7. The power rail generation system of claim 6, wherein the code generator comprises a first adaptive diode configured to receive the digital code and to generate the adaptive voltage based on the digital code.

8. The power rail generation system of claim 7, further comprising a first level shifter configured to shift the digital code to a first voltage domain prior to providing the digital code to the first adaptive diode.

9. The power generation system of claim 2, wherein the first power rail generator comprises a second adaptive diode configured to receive the digital code and to generate the first power rail voltage using the digital code.

10. The power generation system of claim 9, wherein the first power rail generator comprises a second level shifter configured to shift the digital code to a second voltage domain prior to providing the digital code to the second adaptive diode.

11. The power generation system of claim 1, wherein the first power rail generator is configured to:
generate a second power rail voltage for a second gate driver, the second gate driver being configured to drive a switching operation of a second power switch of the first switching converter; and
regulate the second power rail voltage to have a substantially constant second voltage difference from a second local voltage during operation of the first switching converter.

12. The power rail generation system of claim 11, further comprising:
a code generator configured to:
generate a digital code; and
provide the digital code to the first power rail generator;
wherein the first power rail generator is configured to generate the first power rail voltage and the second power rail voltage using the digital code.

13. The power rail generation system of claim 12, wherein the code generator comprises a bit counter configured to generate the digital code.

14. The power rail generation system of claim 13, wherein the bit counter is configured to receive a first clock signal and a digital supply voltage.

15. The power rail generation system of claim 14, further comprising a decision circuit configured to provide an up signal and a down signal to the bit counter, wherein the bit counter is configured to generate the digital code based on the up signal and the down signal.

16. The power rail generation system of claim 15, wherein the decision circuit comprises a first comparator configured to compare an adaptive voltage with a first reference voltage and to generate a comparator output signal based on the comparison, the up signal and the down signal being dependent on the comparator output signal.

17. The power generation system of claim 12, wherein the first power rail generator comprises:
a second adaptive diode configured to receive the digital code and to generate the first power rail voltage using the digital code; and
a third adaptive diode configured to receive the digital code and to generate the second power rail voltage using the digital code.

18. The power generation system of claim 1, further comprising:
a second power rail generator configured to:
generate a third power rail voltage for a third gate driver, the third gate driver being configured to drive a switching operation of a third power switch of a second switching converter; and
regulate the third power rail voltage to have a substantially constant third voltage difference from a third local voltage during operation of the second switching converter.

19. An apparatus comprising:
a plurality of switching converters; and
a power rail generation system comprising a plurality of power rail generators;
wherein:
each of the switching converters comprises one of the plurality of power rail generators; and
each of the power rail generators is configured to:
generate a power rail voltage for a gate driver of the switching converter that the power rail generator is part of, the gate driver being configured to drive a switching operation of a power switch of the switching converter; and
regulate the power rail voltage to have a substantially constant voltage difference from a local voltage during operation of the switching converter.

20. A method of power rail generation, the method comprising:
generating a first power rail voltage for a first gate driver, the first gate driver being configured to drive a switching operation of a first power switch of a first switching converter; and
regulating the first power rail voltage to have a substantially constant first voltage difference from a first local voltage during operation of the first switching converter.
